(19) United States
(12) Patent Application Publication
(10) Pub. No.: US 2016/0190453 A1
(43) Pub. Date: Jun. 30, 2016

(54) ELEMENT MANUFACTURING METHOD AND ELEMENT MANUFACTURING APPARATUS

(71) Applicant: DAI NIPPON PRINTING CO., LTD., Shinjuku-ku, Tokyo-to (JP)

(72) Inventors: Takayoshi NIRENGI, Tokyo-to (JP); Toshihiko TAKEDA, Tokyo-to (JP); Hiroyoshi NAKAJIMA, Tokyo-to (JP); Hiroyuki NISHIMURA, Tokyo-to (JP); Katsunari OBATA, Tokyo-to (JP)

(73) Assignee: DAI NIPPON PRINTING CO., LTD., Shinjuku-ku, Tokyo-to (JP)

(21) Appl. No.: 14/909,317

(22) PCT Filed: Jul. 31, 2014
(86) PCT No.: PCT/JP2014/070235

§ 371 Date: Feb. 1, 2016

(30) Foreign Application Priority Data
Jul. 31, 2013 (JP) 2013-159456

(51) Int. Cl. H01L 51/00; B23K 26/00; B23K 26/352

(52) U.S. Cl. CPC H01L 51/0016; B23K 26/352; B23K 26/0006

(57) ABSTRACT

An intermediate product includes a substrate and a plurality of protrusions disposed on the substrate. A lid member with a first surface is set in place for the first surface to be oriented toward the protrusions of the intermediate product. In a lid member pressing step, on the first surface of the lid member, a shape curved to protrude toward the intermediate product is formed and a section of the lid member that is formed with the curved shape is brought into close contact with a part of the intermediate product.

### TECHNICAL FIELD

The present disclosure relates to an element manufacturing method and element manufacturing apparatus for manufacturing elements such as organic semiconductor elements.

### BACKGROUND ART

Manufacturing processes for such elements as an organic semiconductor element and inorganic semiconductor element are commonly performed under a vacuum environment to prevent impurities from entering the element. For example, sputtering, vapor deposition, or other techniques designed to form films under the vacuum environment are used to form cathodic electrodes, anodic electrodes, and semiconductor layers on a substrate. An internal region of an element manufacturing apparatus is deaerated over a predetermined time using a vacuum pump and other means to realize the vacuum environment.

In the manufacturing processes for the above elements, various steps are executed in addition to a film deposition step. These steps include ones that are traditionally executed under atmospheric pressure. To realize the vacuum environment, on the other hand, the predetermined time is needed as discussed above. Accordingly, when in addition to the film deposition step executed under the vacuum environment the steps executed under atmospheric pressure are further included in the manufacturing processes for such an element, a great deal of time is needed for deaerating the inside of the element manufacturing apparatus or replacing an internal environment of the element manufacturing apparatus with atmospheric air. In light of this factor, it is desirable that the element manufacturing steps be executed under an environment whose pressure is lower than atmospheric pressure. This enables reduction in the time and costs needed to obtain one element.

Examples of steps other than film deposition include the step of removing an organic semiconductor layer positioned on an auxiliary electrode. Patent Document 1, for example, describes such a step. When an electrode disposed on the organic semiconductor layer is a common electrode of a thin-film form, the auxiliary electrode is disposed to suppress a location-by-location difference in magnitude of a voltage drop developed across the common electrode. That is to say, connecting the common electrode to the auxiliary electrode at various locations allows the voltage drop across the common electrode to be reduced. Meanwhile, since the organic semiconductor layer is in general provided over an entire region of the substrate, the above-discussed removal step for removing the organic semiconductor layer on the auxiliary electrode needs to be executed to connect the common electrode to the auxiliary electrode.

A known method for removing an organic semiconductor layer present on an auxiliary electrode is by irradiating the organic semiconductor layer with light such as laser light. In this case, the organic semiconductor material constituting the organic semiconductor layer will fly apart during the removal of the organic semiconductor layer by ablation. To prevent contamination with the organic semiconductor material that has flown apart, therefore, it is preferable that the substrate be covered with some appropriate kind of material. Patent Document 1, for example, proposes a method in which first a counter substrate is overlaid upon the substrate under a vacuum environment to constitute an overlay substrate, next while a space between the counter substrate and the substrate is being maintained under the vacuum atmosphere, the overlay substrate is taken out from the vacuum environment into the atmospheric air, and after this operation, the organic semiconductor layer is irradiated with laser light. Based on a differential pressure between the vacuum atmosphere and the atmospheric air, this method enables the counter substrate to be brought into strong and close contact with the substrate, thereby enabling reliable prevention of contamination with the organic semiconductor material that has flown apart.

### PRIOR ART DOCUMENT

### Patent Document

### PATENT Document 1: JP No. 4340982

### SUMMARY OF THE INVENTION

The step of irradiating organic semiconductor layers with laser light is commonly performed in order upon each of the organic semiconductor layers formed on the plurality of auxiliary electrodes on the substrate. For example, the organic semiconductor layers on the plurality of auxiliary electrodes are sequentially irradiated with the laser light while one of the optical system, which directs the laser light toward the substrate and guides the laser light to the substrate, and the substrate, is being moved relative to the other. Accordingly, there is no need to cover the substrate over its entire region with the counter substrate for the purpose of preventing the organic semiconductor material from flying apart, and a section of the substrate that is to be irradiated with the laser light needs only to be covered with at least the counter substrate. Meanwhile, as in the invention described in Patent Document 1, when the differential pressure between a vacuum atmosphere and the air is used, the substrate is covered over the entire region with the counter substrate. This leads the apparatus configuration to one that is more complex than actually required. In addition, in the invention described in Patent Document 1, a great deal of time is needed for deaerating the inside of the element manufacturing apparatus or replacing an internal environment of the element manufacturing apparatus with atmospheric air.

An embodiment of the present invention has been made with the above in mind, and an object of the invention is to provide an element manufacturing method and element manufacturing apparatus adapted for efficiently covering the section of a substrate that is to be irradiated with laser light.

An embodiment of the present invention is an element manufacturing method for forming an element on a substrate, the method including the step of providing an intermediate product that includes the substrate and a plurality of protrusions each disposed on the substrate, the step of providing a lid member having a first surface, the lid member being provided so that the first surface faces toward the protrusions of the intermediate product, and the step of pressing the lid member to bring a part of the first surface thereof into close contact with a part of the intermediate product, wherein, in the lid member pressing step, on the first surface of the lid member, a shape protrudingly curved toward the intermediate product is formed and a section of the lid member that includes the curved shape is brought into close contact with a part of the intermediate product.

In the element manufacturing method according to an embodiment of the present invention, in addition to the first surface, the lid member may include a second surface that lies on a side opposite to the first surface. In this case, in the lid member pressing step, part of the second surface of the lid member may be pressed toward the intermediate product by use of a lid member pressing mechanism to bring a part of the first surface of the lid member into close contact with a part of the intermediate product.

In the element manufacturing method according to an embodiment of the present invention, the lid member pressing mechanism may include a roller that rotates around a rotational axis of the roller. In this case, in the lid member pressing step, the roller may press part of the second surface of the lid member toward the intermediate product, whereby a shape curved along an outer circumferential surface of the roller may be formed on a region of the first surface of the lid member that corresponds to the second surface thereof.

In the element manufacturing method according to an embodiment of the present invention, the lid member pressing mechanism may include a pressurizing film of a long-size shape that is transported while being retained to form a shape protrudingly curved toward the lid member. In this case, in the lid member pressing step, the curved section of the pressurizing film may press part of the second surface of the lid member toward the intermediate product, whereby a shape curved along the curved section of the pressurizing film may be formed on the first surface of the lid member that corresponds to the second surface thereof.

The element manufacturing method according to an embodiment of the present invention may further include an irradiation step to emit light toward a section of the lid member that is formed with the curved shape. In this case, in the irradiation step, the light may pass through the section of the lid member that is formed with the curved shape, and reach the intermediate product. In addition, in the irradiation step, the light may be emitted from a direction of the substrate within the intermediate product, toward the lid member in close contact with the intermediate product.

The element manufacturing method according to an embodiment of the present invention may further include an irradiation step to emit light toward a section of the lid member that is formed with the curved shape, and in the irradiation step, the light may be guided by an optical system fixed with respect to the rotation of the roller, pass through the lid member, and reach the intermediate product.

In this case, the roller may include a main body constructed of a light-transmissive material to transmit light, the main body constituting the outer circumferential surface of the roller, and in the irradiation step, after the light has passed through an internal space of the roller, the light may pass through the main body of the roller and the lid member and reach the intermediate product. In addition, a mask with a plurality of openings may be disposed in the internal space of the roller, and in the irradiation step, after the light has passed through the openings of the mask, the light may pass through the main body of the roller and the lid member and reach the intermediate product.

Furthermore, the roller may include a main body internally formed with a space, the main body constituting the outer circumferential surface of the roller, a plurality of through-holes each extending from the outer circumferential surface to the internal space may be formed on the main body, and in the irradiation step, after the light has passed through the through-holes of the main body, the light may pass through the lid member and reach the intermediate product.

In the element manufacturing method according to an embodiment of the present invention, the element may include the substrate, a plurality of first electrodes each disposed on the substrate, auxiliary electrodes each disposed between any two of the first electrodes, the protrusions also each disposed between any two of the first electrodes, an organic semiconductor layer disposed on the first electrodes, and a second electrode disposed on the organic semiconductor layer and the auxiliary electrodes, the intermediate product may include the substrate, the first electrodes disposed on the substrate, the auxiliary electrodes and protrusions each disposed between any two of the first electrodes, and the organic semiconductor layer disposed on the first electrodes and the auxiliary electrodes, and the organic semiconductor layer disposed on one of the auxiliary electrodes may be removed while the section of the lid member that is formed with the curved shape is in close contact with a part of the intermediate product.

An embodiment of the present invention is an element manufacturing apparatus for forming an element on a substrate, the apparatus including a transport mechanism for transporting an intermediate product including the substrate and a plurality of protrusions each disposed on the substrate, a lid member supply mechanism for supplying a lid member having a first surface, the mechanism supplying the lid member so that the first surface faces the protrusions of the intermediate product, and a lid member pressing mechanism for bringing a part of the first surface of the lid member into close contact with a part of the intermediate product, wherein, on the first surface of the lid member that is being pressed by the lid member pressing mechanism, a shape protrudingly curved toward the intermediate product is formed and a section of the lid member that includes the curved shape is brought into close contact with a part of the intermediate product.

In the element manufacturing apparatus according to an embodiment of the present invention, in addition to the first surface, the lid member may include a second surface that lies on a side opposite to the first surface. In this case, the lid member pressing mechanism may press a part of the second surface of the lid member toward the intermediate product, whereby part of the first surface of the lid member may come into close contact with a part of the intermediate product.

In the element manufacturing apparatus according to an embodiment of the present invention, the lid member pressing mechanism may include a roller that rotates around a rotational axis of the roller. In this case, a shape curved along an outer circumferential surface of the roller may be formed on the first surface of the lid member that corresponds to the second surface thereof that is being pressed by the roller.

In the element manufacturing apparatus according to an embodiment of the present invention, the lid member pressing mechanism may include a pressurizing film of a long-size shape that is transported while being retained to form a shape protrudingly curved toward the lid member. In this case, the curved section of the pressurizing film may press part of the second surface of the lid member toward the intermediate product, whereby a shape curved along the curved section of the pressurizing film may be formed on the first surface of the lid member that corresponds to the second surface thereof.

The element manufacturing apparatus according to an embodiment of the present invention may further include an irradiation mechanism for emitting light toward a section of the lid member that is formed with the curved shape. In this case, the light may pass through the section of the lid member that is formed with the curved shape, and reach the intermediate product. In addition, the light may be emitted from a direction of the substrate within the intermediate product, toward the lid member in close contact with the intermediate product.

The element manufacturing apparatus according to an embodiment of the present invention may further include an irradiation mechanism for emitting light toward a section of the lid member that is formed with the curved shape, wherein the irradiation mechanism may include an optical system that guides the light so that the light will pass through the lid member and reach the intermediate product, and wherein the optical system may be fixed with respect to the rotation of the roller. In this case, the roller may include a main body constructed of a light-transmissive material to transmit light and internally formed with a space, the main body constituting the outer circumferential surface of the roller, and the irradiation mechanism may be configured so that the light, after passing through an internal space of the roller, passes through the main body and the lid member and reaches the intermediate product. In addition, a mask with a plurality of openings may be disposed in the internal space of the roller, and the irradiation mechanism may be configured so that the light, after passing through the openings of the mask, passes through the main body and the lid member and reaches the intermediate product.

Furthermore, the roller may include a main body internally formed with a space, the main body constituting the outer circumferential surface of the roller, a plurality of through-holes each extending from the outer circumferential surface to the internal space may be formed on the main body, and the irradiation mechanism may be configured so that the light, after passing through the through-holes of the main body, passes through the lid member and reaches the intermediate product.

In the element manufacturing apparatus according to an embodiment of the present invention, the roller may include a first roller and a second roller, both lined up spacedly in the second direction. In this case, the first roller and the second roller may act together to press the second surface of the lid member, whereby a section of the lid member that is positioned between the first roller and the second roller may have a shape curved along an outer circumferential surface of the first roller and an outer circumferential surface of the second roller.

According to the embodiment of the present invention, a substrate can be efficiently covered using an apparatus of a simplified configuration.

### BRIEF DESCRIPTION OF THE DRAWINGS

FIG. 1 is a longitudinal sectional view of an organic semiconductor element according to an embodiment of the present invention.

FIG. 2A is a plan view of an exemplary layout of auxiliary electrodes, protrusions, and organic semiconductor layers of the organic semiconductor element shown in FIG. 1.

FIG. 2B is a plan view of another exemplary layout of the auxiliary electrodes, protrusions, and organic semiconductor layers of the organic semiconductor element shown in FIG. 1.

FIG. 2C is a plan view of an example of a section of the organic semiconductor layers which is to be removed on the auxiliary electrodes.

FIG. 2D is a plan view of an example of a section of the organic semiconductor layers which is to be removed on the auxiliary electrodes.

FIG. 3 is a diagram showing an element manufacturing apparatus according to the present invention.

FIG. 4 (a) to (g) show an element manufacturing method according to the embodiment of the present invention.

FIG. 5 is a diagram showing an intermediate product processing device used to remove the organic semiconductor layers from the auxiliary electrodes.

FIG. 6 is a diagram showing the way the organic semiconductor layer on auxiliary electrode is removed by using the intermediate product processing device shown in FIG. 5.

FIG. 7 (a) to (g) show the step of removing an organic semiconductor layer from an auxiliary electrode in a modification of the embodiment of the present invention.

FIGS. 8 (a) and (b) show an example in which the intermediate product processing device is used to vapor-deposit a vapor-deposit material on a substrate.

FIG. 9 is a diagram showing a modification of an optical system disposed in an internal space of a roller.

FIG. 10 is a diagram showing a modification of the roller.

FIG. 11 is a diagram showing modification of the roller.

FIG. 12A is a diagram showing an example in which a lid member pressing mechanism includes a pressurizing film.

FIG. 12B is a diagram showing the way a lid member is pressed by the pressurizing film shown in FIG. 12A.

FIG. 13A is a diagram showing an example in which the roller has a surface functioning as a first surface of the lid member that comes into close contact with part of an intermediate product.

FIG. 13B is a diagram showing an example in which the surface of the roller shown in FIG. 13A is in close contact with part of the intermediate product.

FIGS. 14 (a) and (b) are diagrams showing an example in which the organic semiconductor layer is irradiated with light from the side of the substrate.

### MODES FOR CARRYING OUT THE INVENTION

Hereunder, embodiments of the present invention will be described with reference to FIGS. 1 to 6. In the drawings accompanying the present Description, for the sake of illustration and easier understanding, scales, horizontal to vertical ratios, etc. are exaggeratingly modified from those of the real thing.

A layer configuration of an organic semiconductor element 40 according to an embodiment of the present invention will be first described with reference to FIG. 1. Here, a top-emission type of organic electroluminescent (EL) element will be described as an example of the organic semiconductor element 40.

### Organic Semiconductor Element

As shown in FIG. 1, the organic semiconductor element 40 includes a substrate 41, a plurality of first electrodes 42 each disposed on the substrate 41, auxiliary electrodes 43 and protrusions 44 each disposed between any two of the first electrodes 42, organic semiconductor layers 45 each disposed on one of the first electrodes 42, and a second electrode 46 disposed on the organic semiconductor layers 45 and on the auxiliary electrodes 43.

The organic semiconductor layers 45 each include at least a light-emitting layer that emits light by recombinations of electrons and holes in organic compounds. Each organic semiconductor layer 45 may further include a hole injection layer, a hole transport layer, an electron transport layer or an electron injection layer, and other layers generally provided in an organic EL element. Constituent elements of the organic semiconductor layer can be known ones, for example the elements described in JP2011-9498A.

One first electrode 42 is disposed for each of the organic semiconductor layers 45. The first electrode 42 also functions as a reflecting electrode to reflect the light that has been generated from the organic semiconductor layer 45. Examples of a material constituting the first electrode 42 can include aluminum, chromium, titanium, iron, cobalt, nickel, molybdenum, copper, tantalum, tungsten, platinum, gold, silver, and other metallic elements, whether they be present independently or in combination as an alloy.

The second electrode 46 functions as a common electrode with respect to the plurality of organic semiconductor layers 45. In addition, the second electrode 46 is configured to transmit the light that has been generated from the organic semiconductor layers 45. Examples of a material constituting the second electrode 46 can include a metallic film that has been thinned to such an extent that it can transmit the light, and an oxide conductive material such as indium tin oxide (ITO).

The auxiliary electrodes 43 are provided to suppress variations in voltage drop due to differences in distances from a power supply (not shown) to individual organic semiconductor layers, and thus to suppress a variation in luminance of a display device which uses the organic EL element. As shown in FIG. 1, each auxiliary electrode 43 is connected to the second electrode 46. Examples of a material constituting the second electrode 46 can include substantially the same metallic elements as those which are each used alone in the first electrode 42 or in combination as an alloy. The auxiliary electrodes 43 may be formed from the same material as that of the first electrode 42, or may be formed from a material different from that of the first electrode 42.

The protrusions 44 are constructed of a material having an electrical insulating property. In the example of FIG. 1, the protrusions 44 are each disposed between one first electrode 42 and one auxiliary electrode 43. Disposing each such protrusion 44 enables electrical insulation between the first electrode 42 and the auxiliary electrode 43, and between the first electrode 42 and the second electrode 46. The disposition of each protrusion 44 also enables appropriate definition of a shape of the organic semiconductor layers 45 each disposed between any two of the protrusions 44. Examples of a material constituting the protrusions 44 can include an organic material such as polyimide, and an inorganic insulating material such as silicon oxide. In addition, the protrusions 44 extend in a normal-line direction of the substrate 41 and thus when a lid member described later herein is brought into close contact with the substrate 41, the protrusions can also be made to function as spacers to ensure a space between the lid member and the substrate 41.

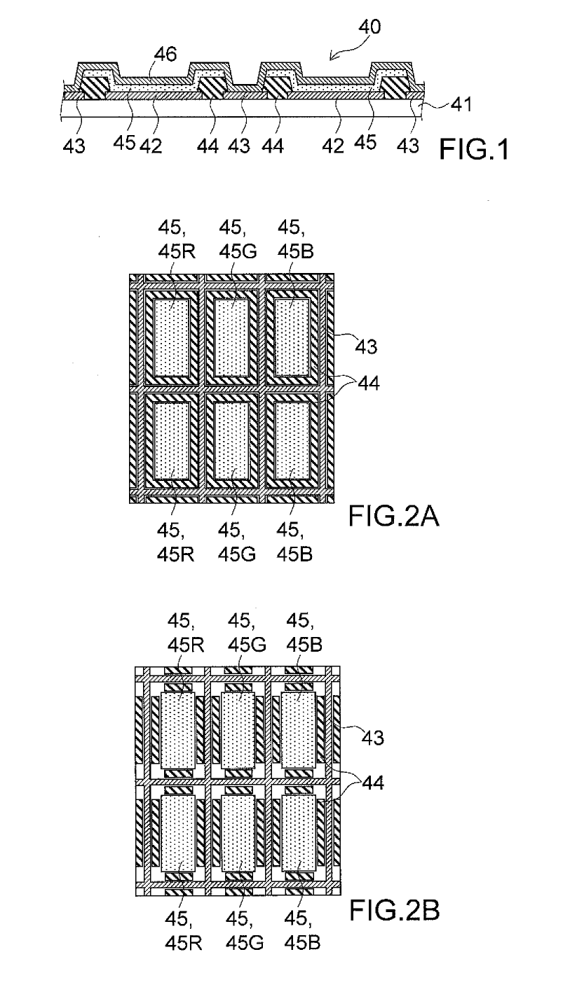

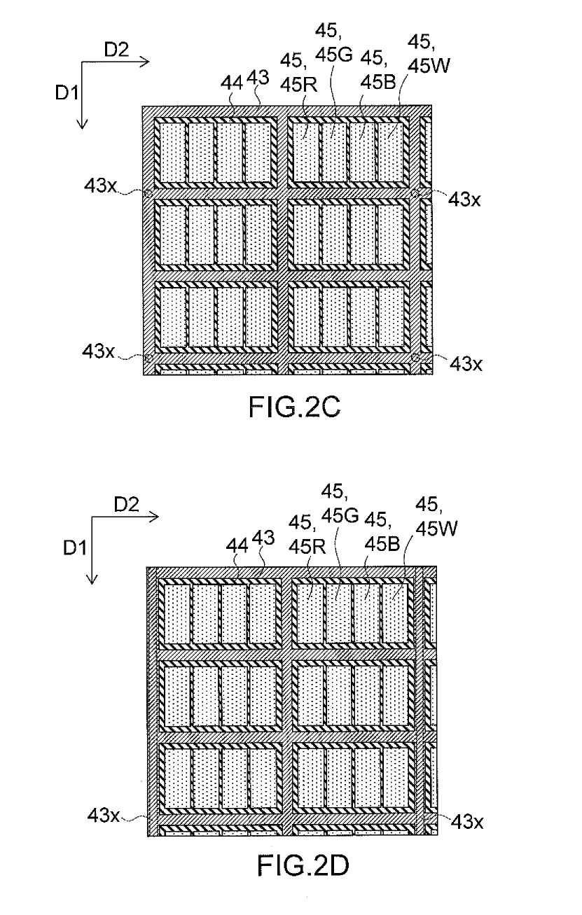

As shown in FIG. 1, the organic semiconductor layers 45 and the second electrode 46 may be continuously disposed on the protrusions 44 as well as on the first electrodes 42. Of each organic semiconductor layer 45, only a region sandwiched between one first electrode 42 and the second electrode 46 upward and downward allows an electric current to flow through and emits light, and regions of the organic semiconductor layer 45 that are positioned on the protrusions 44 do not emit light. Only the region of the organic semiconductor layer 45 that emits the light, that is, the organic semiconductor layer 45 disposed on the first electrode 42, is shown in FIGS. 2A and 2B that are described later herein.

Next, construction of the organic semiconductor element 40 when viewed from the normal-line direction of the substrate 41 is described below. The description focuses particularly upon layout of the auxiliary electrodes 43, protrusions 44, and organic semiconductor layers 45 of the organic semiconductor element 40. FIG. 2A is a plan view of exemplary layout of the auxiliary electrodes 43, the protrusions 44, and the organic semiconductor layers 45. As shown in FIG. 2A, the organic semiconductor layers 45 may be arranged sequentially in matrix form and each may include a rectangular, red organic semiconductor layer 45R, green organic semiconductor layer 45G, and blue organic semiconductor layer 45B. In this case, the red organic semiconductor layer 45R, the green organic semiconductor layer 45G, and the blue organic semiconductor layer 45B each constitute a sub-pixel. In addition, a combination of adjacent organic semiconductor layers 45R, 45G, and 45B constitutes one pixel.

As shown in FIG. 2A, the auxiliary electrodes 43 are arranged in grid form in such a way as to extend between the organic semiconductor layers 45 arranged in the matrix form. Location-specific differences in magnitude of the voltage drop across the second electrode 46 connected to the organic semiconductor layers 45 can be suppressed by arranging the auxiliary electrodes 43 in this way. Additionally, as shown in FIG. 2A, the protrusions 44 are each disposed between one organic semiconductor layer 45 and one auxiliary electrode 43 so as to surround the organic semiconductor layer 45 disposed on the first electrode 42 from the side thereof. In other words, each protrusion 44 is continuously disposed along four sides of the organic semiconductor layer 45 disposed on the first electrode 42. Thus, the organic semiconductor material that may have flown apart in the step of removing the organic semiconductor layer 45 positioned on the auxiliary electrode 43 can be prevented from reaching the organic semiconductor layer 45 on the first electrode 42.

As long as the voltage drop can be appropriately reduced, the auxiliary electrode 43 does not need to be connected to the second electrode 46 over an entire region of the auxiliary electrode 43. That is to say, not all of the organic semiconductor layer 45 on the auxiliary electrode 43 requires removal in the removal step detailed later herein. As shown in FIG. 2B, therefore, the protrusion 44 may be discontinuously disposed along any one of the four sides of the organic semiconductor layer 45. In the example of FIG. 2B as well, the organic semiconductor material that may have flown apart in the step of removing the organic semiconductor layer 45 on the auxiliary electrode 43 positioned between two protrusions 44 can be prevented from reaching the organic semiconductor layer 45 on the first electrode 42, which organic semiconductor layer 45 is at least partially positioned between two protrusions 44. In addition, the voltage drop can be appropriately suppressed by connecting the auxiliary electrode 43 positioned between the two protrusions 44 to the second electrode 46.

Furthermore, the layout of the auxiliary electrodes 43 is not limited as long as the voltage drop across the second electrode 46 can be appropriately reduced. For example, as shown in FIGS. 2C and 2D, the auxiliary electrodes 43 may be disposed along the pixels constituted by the organic semiconductor layers 45R, 45G, 45B, and 45W corresponding to a plurality of sub-pixels. In other words, the auxiliary electrodes 43 may be absent between the organic semiconductor layers 45R, 45G, 45B, and 45W that constitute sub-pixels, and one auxiliary electrode 43 may be formed between one of the pixels constituted by the organic semiconductor layers 45R, 45G, 45B, and 45W, and other similar pixels. Examples in which each pixel further includes the white organic semiconductor layer 45W as a sub-pixel in addition to the red organic semiconductor layer 45R, the green organic semiconductor layer 45G, and the blue organic semiconductor layer 45B are shown in FIGS. 2C and 2D.

Moreover, layout of positions in which the auxiliary electrodes 43 and the second electrode 46 are connected is not limited as long as the voltage drop across the second electrode 46 can be appropriately reduced. In FIGS. 2C and 2D, the positions where the auxiliary electrodes 43 and the second electrode 46 are connected are each shown by a dotted line denoted as reference number 43x. As shown in FIG. 2C, each auxiliary electrode 43 and the second electrode 46 may be connected discretely at a plurality of places. That is to say, the organic semiconductor layer 45 on the auxiliary electrode 43 may be removed discretely at a plurality of places. In addition, as shown in FIG. 2D, each auxiliary electrode 43 and the second electrode 46 may be connected linearly along a direction the auxiliary electrode 43 extends. That is to say, the organic semiconductor layer 45 on the auxiliary electrode 43 may be removed linearly along the direction the auxiliary electrode 43 extends. An example in which the organic semiconductor layer 45 on the auxiliary electrode 43 is removed linearly along a direction D1 in which the lid member 21 is transported described in detail later herein is shown in FIG. 2D.

In FIGS. 2A to 2D, an example in which the plurality of kinds of organic semiconductor layers, namely 45R, 45G, 45B, and 45W, are used as organic semiconductor layers 45, is shown, which is not limited. For example, each organic semiconductor layer constituting a sub-pixel may be configured to generate common white light. In this case, a color filter, for example, could be used as means for color-coding the sub-pixels.

Next, a description will be given of an element manufacturing apparatus 10 and an element manufacturing method according to the embodiment, both intended to form the organic semiconductor element 40 on the substrate 41. As long as impurities can be sufficiently prevented from entering the organic semiconductor element 40, although an environment in which the element manufacturing method is implemented is not limited, the element manufacturing method itself is implemented, for example, partially under a vacuum environment. For example, as long as the environment has a pressure lower than atmospheric pressure, although the more specific pressure in the vacuum environment is not limited, the element manufacturing apparatus 10 has an internal pressure of, for example, 1.0×10⁴ Pa or less.

### Element Manufacturing Apparatus

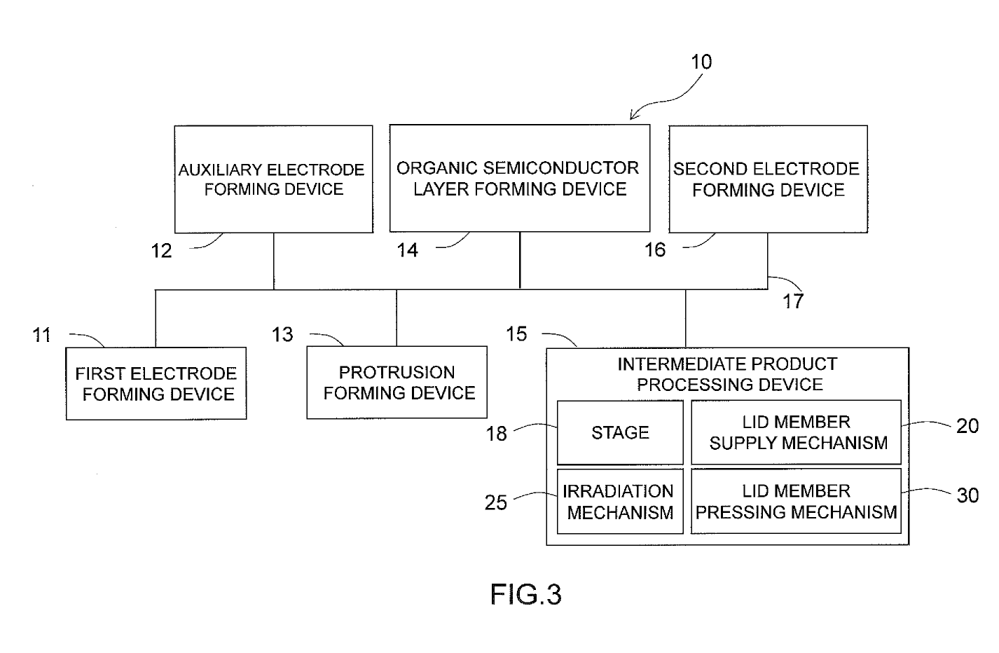

FIG. 3 is a diagram showing schematically a configuration of the element manufacturing apparatus 10. As shown in FIG. 3, the element manufacturing apparatus 10 includes a first electrode forming device 11 that forms a plurality of first electrodes 42 on a substrate 41, an auxiliary electrode forming device 12 that forms an auxiliary electrode 43 between the first electrodes 42, a protrusion forming device 13 that forms a protrusion 44 between the first electrodes 42 and the auxiliary electrodes 43, and an organic semiconductor layer forming device 14 that forms an organic semiconductor layer 45 on each of the first electrodes 42, the auxiliary electrode 43, and the protrusion 44. In the following description, an object obtained in steps that use the devices 11, 12, 13, and 14 may be termed the intermediate product 50.

The element manufacturing apparatus 10 further includes an intermediate product processing device 15 that performs predetermined processing while a lid member described later herein is in close contact with part of the intermediate product 50. Here, a description will be given below of an example in which the intermediate product processing device 15 in the present embodiment is configured as a removal device for removing the organic semiconductor layer 45 disposed on the auxiliary electrode 43. The intermediate product processing device 15 includes a stage 18, a lid member supply mechanism 20, a lid member pressing mechanism 30, and an irradiation mechanism 25. Constituent elements of the intermediate product processing device 15 will be described later herein. The lid member 21 or the element manufacturing apparatus 10 further includes a second electrode forming device 16 that forms a second electrode 46 on the auxiliary electrode 43 and organic semiconductor layer 45 after the organic semiconductor layer 45 on the auxiliary electrode 43 has been removed.

As shown in FIG. 3, the element manufacturing apparatus 10 may further include a transport device 17 connected to the devices 11 to 16 in order to transport the substrate 41 and the intermediate product 50 between the devices 11 to 16.

FIG. 3 is a diagram representing a classification of the devices as viewed from a functional perspective, and these devices do not have respective physical forms limited to the example shown in FIG. 3. For example, more than one of the devices 11 to 16 shown in FIG. 3 may be physically constituted by one device. Alternatively, any one or more of the devices 11 to 16 shown in FIG. 3 may be physically constituted by a plurality of devices. For example, as will be described later herein, at least one of the first electrodes 42 and at least one of the auxiliary electrodes 43 may be formed at the same time in one step. In this case, the first electrode forming device 11 and the auxiliary electrode forming device 12 may be configured collectively as one device.

### Element Manufacturing Method

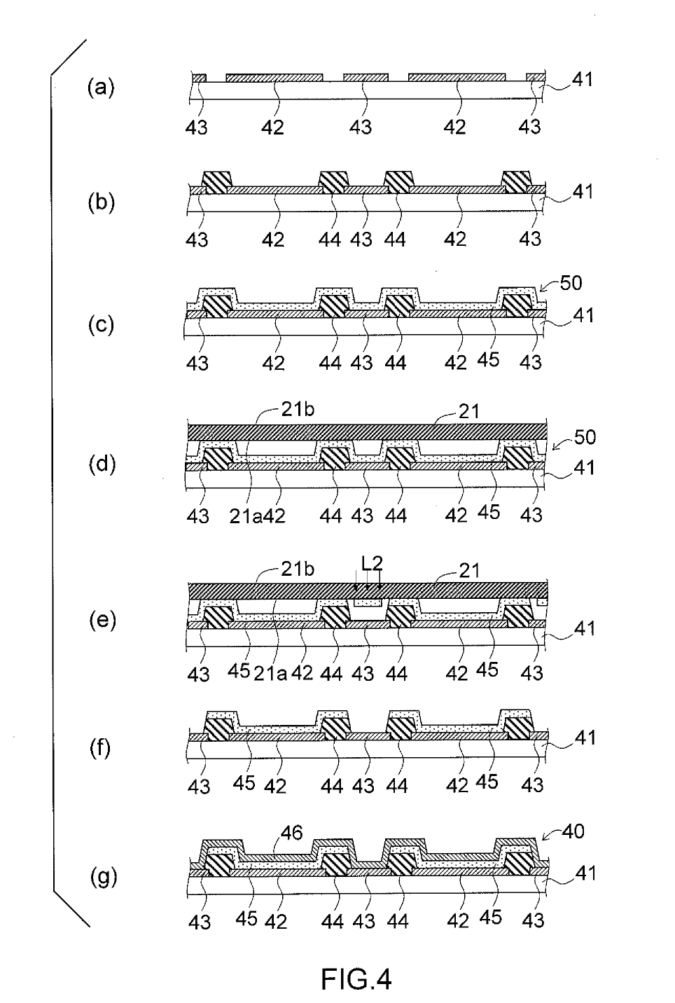

The method of manufacturing the organic semiconductor element 40 using the element manufacturing apparatus 10 will be described below with reference to FIG. 4 (a) to (g). First, a layer of a metallic material which constitutes first electrodes 42 and auxiliary electrodes 43 is formed on the substrate 41 by use of a sputtering method, for example, and then the layer of the metallic material is molded by etching. Thus the first electrodes 42 and the auxiliary electrodes 43 can be formed at the same time on the substrate 41, as shown in FIG. 4 (a). The first electrodes 42 and the auxiliary electrodes 43 may be formed in steps independent of each other.

Next as shown in FIG. 4 (b), a plurality of protrusions 44 each extending to a region above one of the first electrodes 42 and one of the auxiliary electrodes 43, in a normal-line direction of the substrate 41, are formed between the first electrode 42 and the auxiliary electrode 43 by means of photolithography, for example. After the formation of the protrusions 44, as shown in FIG. 4 (c), an organic semiconductor layer 45 is formed on the first electrodes 42, the auxiliary electrodes 43, and the protrusions 44, by use of a general film-forming method such as physical vapor deposition, chemical vapor deposition (CVD), printing, inkjet coating, or transfer. In this manner, an intermediate product 50 can be obtained that includes the substrate 41, the first electrodes 42 disposed on the substrate 41, the auxiliary electrodes 43 and protrusions 44 each disposed between the first electrodes 42, and the organic semiconductor layer 45 disposed on the first electrodes 42, the auxiliary electrodes 43, and the protrusions 44. In the present embodiment, as described above, the first electrodes 42 and the auxiliary electrodes 43 are formed on the substrate 41 earlier than the protrusions 44. Accordingly the first electrodes 42 and the auxiliary electrodes 43 are partly covered with the protrusions 44.

Next, a lid member 21 is provided and then as shown in FIG. 4 (d), it's a first surface 21a of the lid member 21 is brought into close contact with part of the intermediate product 50. Next, while as shown in FIG. 4 (e), the lid member 21 is in close contact with the intermediate product 50, the organic semiconductor layer 45 disposed on one of the auxiliary electrodes 43 is irradiated with light L2 such as laser light. Energy from the light L2 is then absorbed by the organic semiconductor layer 45 and consequently the organic semiconductor material constituting the organic semiconductor layer 45 on the auxiliary electrode 43 flies apart. In this way, the organic semiconductor layer 45 on the auxiliary electrode 43 can be removed. The organic semiconductor material that has flown apart from a surface of the auxiliary electrode 43 sticks to the first surface 21a of the lid member 21, as shown in FIG. 4 (e), for example. FIG. 4 (f) shows the state where a part of the organic semiconductor layers 45 on the auxiliary electrodes 43 has been removed.

Next, as shown in FIG. 4 (g), the second electrode 46 is formed on the organic semiconductor layers 45 positioned on the first electrodes 42, and on the auxiliary electrodes 43. In this way, the organic semiconductor element 40 with the auxiliary electrodes 43 connected to the second electrode 46 can be obtained.

### Intermediate Product Processing Device

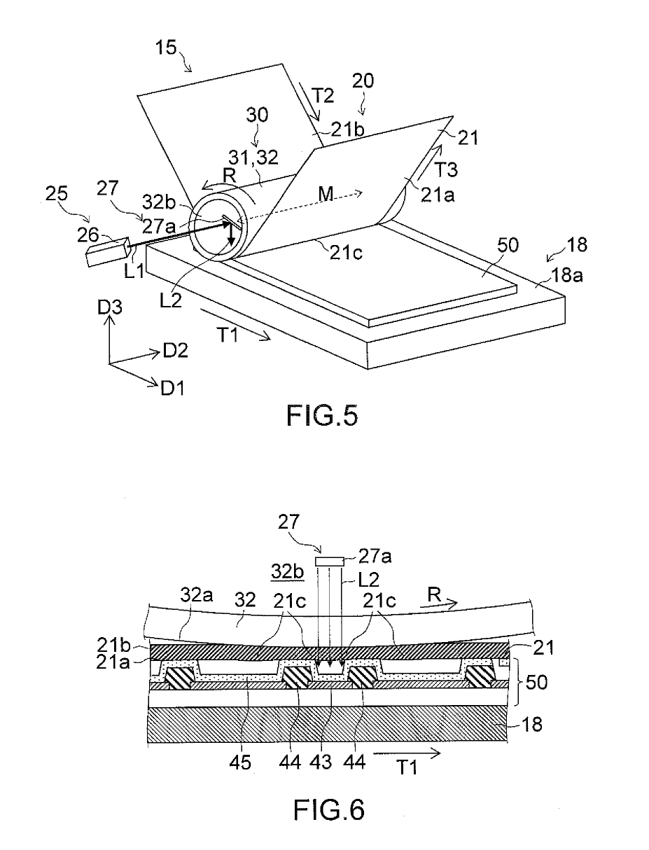

The method of bringing the lid member 21 into close contact with part of the intermediate product 50 and removing the organic semiconductor layer 45 on the auxiliary electrode 43 has been described with reference to FIG. 4 (d) and FIG. 4 (e). Further details of this method will be described below with reference to FIGS. 5 and 6. The intermediate product processing device 15 implements the steps shown in FIG. 4 (d) and FIG. 4 (e). First, a configuration of the intermediate product processing device 15 is described in detail below with reference to FIG. 5. In FIG. 5, a first direction, a second direction, and a third direction, which are orthogonal to each other, are denoted as arrows D1, D2, and D3, respectively.

As shown in FIG. 5, the intermediate product processing device 15 includes a stage 18 on which the intermediate product 50 is mounted, a lid member supply mechanism 20 that supplies the lid member 21 of a long-size shape, a lid member pressing mechanism 30 that brings part of the lid member 21 into close contact with part of the intermediate product 50, and an irradiation mechanism 25 that irradiates with light a section of the intermediate product 50 that the lid member 21 is kept in close contact with. Elements of the intermediate product processing device 15 are arranged in a chamber maintained in a vacuum atmosphere. Accordingly the step of removing the organic semiconductor layer 45 on the auxiliary electrode 43 can be carried out under the vacuum atmosphere. The following describes the elements of the intermediate product processing device 15. The “long-size shape” means that a dimension of the lid member 21 in the direction that it is transported is at least five times a dimension of the lid member 21 in the direction orthogonal to that in which it is transported.

### Stage

The stage 18 has a mounting surface 18a for supporting the intermediate product 50, and the mounting surface 18a has an expanse that is parallel to the first direction D1 and the second direction D2. In addition, the stage 18 is configured to be movable in a moving direction T1 of the stage that is parallel to the first direction D1. The intermediate product 50 is mounted on the stage 18 so that the plurality of protrusions 44 line up on the substrate 41, in the first direction D1. Accordingly, as will be described later herein, either the protrusions 44 of the intermediate product 50 that are lined up in the first direction D1, or peripheral sections of the protrusions 44 can be sequentially irradiated with light by repeating movement of the stage 18 in the moving direction T1 thereof and irradiating the intermediate product 50 with light from the irradiation mechanism 25. The protrusions 44 of the intermediate product 50 mounted on the stage 18 extend in the third direction D3 that is orthogonal to the first direction D1 and the second direction D2.

### Lid Member Supply Mechanism and the Lid Member Pressing Mechanism

As shown in FIG. 5, the lid member pressing mechanism 30 includes a roller 31 that rotates in a rotational direction R around a rotational axis of the roller that extends in the second direction D2 orthogonal to the first direction D1. The lid member supply mechanism 20 includes a feeder that feeds the lid member 21 in a feed direction T2, between the roller 31 and the intermediate product 50, and a take-up section that takes up the lid member 21 in a take-up direction T3 after the lid member 21 has moved past between the roller 31 and the intermediate product 50. The feeder and the take-up section are not shown. In the present embodiment with these mechanisms, the lid member 21 for covering a part of the intermediate product 50 is supplied on a roll-to-roll basis. In the following description, of all surfaces of the lid member 21, a surface oriented toward the stage 18 is termed the first surface 21a, and a surface opposite to the first surface 21a is termed the second surface 21b.

At least one of polyethylene terephthalate (PET), cycloolefin polymer (COP), polypropylene (PP), polyethylene (PE), polycarbonate (PC), a glass film, and other materials having a property to transmit light is used as a material for the lid member 21 to allow light such as laser light to pass through.

The roller 31 of the lid member pressing mechanism 30 is constructed to rotate in synchronization with the movement of the stage 18. In other words, after the lid member 21 has been wound around the roller 31, the roller 31 transports the lid member to ensure matching between a moving speed of the stage 18 and a transport speed of the lid member 21. The roller 31 includes a cylindrical main body 32 and a drive for rotating the main body 32 while supporting it at a predetermined position. The main body 32 refers to a section constituting an outer circumferential surface of the roller 31, that is, a surface that comes into contact with the lid member 21. The outer circumferential surface of the roller 31 and that of the main body 32 are therefore synonymous.

A more specific configuration of the drive for rotating the main body 32 is not limited as long as an optical path for emitting light toward the intermediate product 50 is not obstructed.

The main body 32 in the present embodiment is constructed of the light-transmissive materials that transmit light, such as glass. In addition, a space 32b is formed inside the main body 32. For example, the space 32 is configured to allow the main body 32 to penetrate the roller 31, in an axial direction of the roller. Disposing the space 32b allows an optical system 27 (and the like) of the irradiation mechanism 25 to be placed inside the roller 31, as will be described later herein.

### Irradiation Mechanism

As shown in FIG. 5, the irradiation mechanism 25 includes a light source 26 that generates laser light or other light and emits the light toward the internal space 32b of the main body 32 of the roller 31, and an optical system 27 placed inside the internal space 32b of the main body 32. The optical system 27 guides the light so that the light that has been emitted from the light source 26 passes through the main body 32 and the lid member 21 wound around it and reaches the intermediate product 50. The optical system 27 can use, for example, a mirror 27a capable of reflecting the light and thus changing a direction in which the light travels. In FIG. 5 and other figures, the light that was emitted from the light source 26 is denoted by reference number L1 and the light whose traveling direction has been changed by the optical system 27 is denoted by reference number L2.

The optical system 27 is fixed with respect to the movement of the stage 18 and the rotation of the roller 31. That is to say, the optical system 27 is disposed independently of the stage 18 and the roller 31. For example, the optical system 27 is configured so that the traveling direction of the light L2 generated by the optical system 27 will remain unchanged even after the stage 18 has moved or the roller 31 has rotated. Meanwhile, as described above, the stage 18 can be moved in the first direction D1 and the protrusions 44 of the intermediate product 50 are lined up in the first direction D1. Even when the optical system 27 is at rest, therefore, the protrusions 44 or the peripheral sections of the protrusions 44 can be sequentially irradiated with the light. In addition, because of no need to move the optical system 27 in the first direction D1, no misalignment of an aiming line of the optical system 27 occurs during necessary steps. This means that light irradiation can be executed with high positional accuracy relative to irradiating a plurality of sections of the intermediate product 50 with light while moving the light source 26 and/or the optical system 27.

As indicated by a dotted line with arrow M in FIG. 5, the mirror 27a of the optical system 27 may be configured to be movable along the rotational axis of the roller 31 in the internal space 32b of the main body 32 of the roller 31. This allows any section of the intermediate product 50 to be irradiated with the light, as will be described later. A more specific configuration for moving the optical system 27 is not limited. For example, the optical system 27 can, although this is not shown, move along a rail disposed in the internal space 32b of the main body 32. In addition, when the light source 26 and/or the optical system 27 is configured to be able to selectively extract light at a given position in the second direction even under a stationary state of the light source 26 and/or the optical system 27, the intermediate product 50 can be irradiated with the light at that given position in the second direction. A method useable to selectively extract the light at the given position in the second direction would be by selectively shielding openings 28a of a mask 28 shown in FIG. 9 described later herein.

In the case where the intermediate product 50 can be irradiated with the light at that given position in the second direction, sections of the intermediate product 50 that are to be irradiated with the light do not need to line up in the first direction orthogonal to the second direction. Therefore, although this is not shown, the protrusions 44 of the intermediate product 50 do not need to line up in the first direction D1.

Next, a method of removing the organic semiconductor layer 45 on an auxiliary electrode 43 using the intermediate product processing device 15 will be described with reference to FIG. 6.

First the lid member 21 having the first surface 21a is set in place so that the first surface 21a faces the protrusions 44 of the intermediate product 50. A lid member supply step is executed to supply the lid member 21 between the main body 32 of the roller 31 and the intermediate product 50 by use of, for example, the lid member supply mechanism 20 so that the first surface 21a faces the stage 18. Next, a lid member pressing step is executed to press a part of the lid member 21 toward the stage 18 by use of the roller 31 of the lid member pressing mechanism 30. Thus, part of the first surface 21a of the lid member 21 comes into firm contact with a part of the intermediate product 50. More specifically, as shown in FIG. 6, part of the first surface 21a of the lid member 21 comes into close contact with the section of the intermediate product 50 that is provided with the protrusions 44. At this time, a shape curved along the outer circumferential surface 32a of the main body 32 is formed on a section of the first surface 21a that corresponds to the second surface 21b of the lid member 21 pressed by the main body 32 of roller 31. The section where the curved shape has been formed protrudes toward the stage 18, for example, at an interspace between the protrusions 44 of the intermediate product 50. Compared with a case in which the first surface 21a of the lid member 21 is planar, therefore, this method allows the first surface 21a of the lid member 21 to be pressed firmly, without a clearance, against the section of the intermediate product 50 that is provided with the protrusions 44. In the following description, the section of the first surface 21a that includes the curved shape formed along the outer circumferential surface 32a of the main body 32 will also be termed the curved section 21c. In addition, in the present embodiment, the “section of the first surface 21a that corresponds to the second surface 21b of the lid member 21 pressed by the main body 32” means a section of the first surface 21a that lies at a side opposite to the second surface 21b pressed by the main body 32.

The lid member pressing step is followed by an irradiation step, in which step the section of the intermediate product 50 that is in close contact with the lid member 21 is irradiated with light via the lid member 21. Conceptually, the “section of the intermediate product 50 that is in close contact with the lid member 21” encompasses not only the protrusions 44 that are in direct contact with the first surface 21a of the lid member 21, but also sections surrounded by the protrusions 44 that are in direct contact with the first surface 21a of the lid member 21. Not all of the section of the intermediate product 50 that is in close contact with the lid member 21 requires light irradiation. In the present embodiment, only the section of the intermediate product 50 that is in close contact with the lid member 21 and is provided with the organic semiconductor layer 45 to be removed is irradiated with the light. FIG. 6 shows the way the light L2 that has been emitted from the light source 26 and reflected by the mirror 27a of the optical system 27 passes through the main body 32 and the curved section 21c of the lid member 21 and reaches the organic semiconductor layer 45 disposed on an auxiliary electrode 43 of the intermediate product 50. As the organic semiconductor layer 45 absorbs the energy of the light L2, the organic semiconductor material constituting the organic semiconductor layer 45 disposed on the auxiliary electrode 43 will fly apart as described above. The optical system 27 may further include a lens (and the like) for setting a focus of the mirror-reflected light L2 with respect to the organic semiconductor layer 45.

Here in accordance with the present embodiment, as described above, the curved section 21c is formed on the first surface 21a of the lid member 21 and then used to bring the lid member 21 into close contact with the intermediate product 50. This allows the first surface 21a of the lid member 21 to be pressed firmly, without a clearance, against the section of the intermediate product 50 that is provided with the protrusions 44. Accordingly the organic semiconductor material that has flown apart from the surface of the auxiliary electrode 43 can be more reliably prevented from contaminating the organic semiconductor layer 45 on the auxiliary electrode 43, and an ambient environment.

In this manner, a simplified constituent element of the roller 31 can be used to cover part of the intermediate product 50 efficiently with the lid member 21. For this reason, the organic semiconductor element 40 having high quality can be manufactured at a low cost.

Once the organic semiconductor layer 45 on the auxiliary electrode 43 has been removed, the light from the irradiation mechanism 25 is shut down. That is to say, the irradiation of the intermediate product 50 with the light is stopped.

An example in which, at sections of the lid member 21 that do not transmit the light L2, a clearance is formed partially between the main body 32 of the roller 31 and the second surface 21b of the lid member 21, is shown in FIG. 6. However, as long as part of the lid member 21 can be brought into close contact with the intermediate product 50 by using the roller 31, relationships in position between the lid member 21 and the roller 31, at other sections, are not limited. For example, the sections of the lid member 21 that do not transmit the light L2 may be in a state of being in firm contact with the main body 32 of the roller 31 but not being in firm contact with the intermediate product 50.

Next, the stage 18 is moved in the moving direction T1 of the stage and the rid material 21 is moved in the rotational direction R of the main body 32 of the roller 31. After this, when the next organic semiconductor layer 45 to be removed from the surface of the auxiliary electrode 43 reaches the optical path of the light L2 that extends from the optical system 27 to the intermediate product 50, the irradiation mechanism 25 emits light once again. The organic semiconductor layer 45 on the auxiliary electrode 43 is then irradiated with the light L2 from the irradiation mechanism 25 once again, whereby the organic semiconductor layer 45 is removed. In this manner, the organic semiconductor layers 45 on the auxiliary electrodes 43 lined up in the first direction D1 parallel to the moving direction T1 of the stage can be removed in order. The organic semiconductor layers 45 on the auxiliary electrodes 43 are usually arranged at equal intervals above the substrate 41. The organic semiconductor layers 45 on the auxiliary electrodes 43 may therefore be irradiated with the light in order by turning on and off the light source 26 of the irradiation mechanism 25 at fixed periods that allow for intervals of the auxiliary electrodes 43 and the moving speed of the stage 18.

As can be seen from the above, when the stage 18 moves and the main body 32 rotates, the optical system 27 of the irradiation mechanism 25 remains at rest. For this reason, in the present embodiment, the intermediate product 50 can be light-irradiated with high positional accuracy, which in turn allows accurate removal of the organic semiconductor layer 45 from the surface of the auxiliary electrode 43.

In addition, in accordance with the present embodiment, the lid member 21 supplied on a roll-to-roll basis can be used to cover the intermediate product 50 placed on the moving stage 18. Accordingly the step of removing the organic semiconductor layer 45 on the surface of the auxiliary electrode 43 can be executed for a plurality of intermediate products 50 by use of one roll unit having one lid member 21 wound around it. A device or step for cutting the lid member 21 for each intermediate product 50 is therefore unnecessary, for which reason the apparatus configuration and the steps can be simplified. Occurrence of a gas due to the cutting of the lid member 21 and resulting contamination of the intermediate product 50 can also be prevented.

After the above removal, the mirror 27a may be moved along the rotational axis of the roller 31 to remove the organic semiconductor layers 45 on the plurality of auxiliary electrodes 43 positioned on a new line different from that of the first direction D1 in which the organic semiconductor layer 45 has existed until removed in the removal step. After the mirror 27a has been moved, the organic semiconductor layers 45 on the plurality of auxiliary electrodes 43 positioned on the new line can be removed by executing the above step once again while moving the stage 18.

Various changes may be made to the embodiments described above. Modifications will be described with reference being made to part of the accompanying drawings. In the following description and the drawings used therein, the same reference numbers as those which have been used to denote the corresponding elements/sections in the above embodiments will be used for the elements/sections that can be configured similarly to those of the embodiments, and overlapped description will be omitted. In addition, where the operational effects obtained in the embodiments can also be obviously obtained in the modifications, description of these effects may be omitted.

### A Modification of the Layer Configuration in the Organic Semiconductor Element

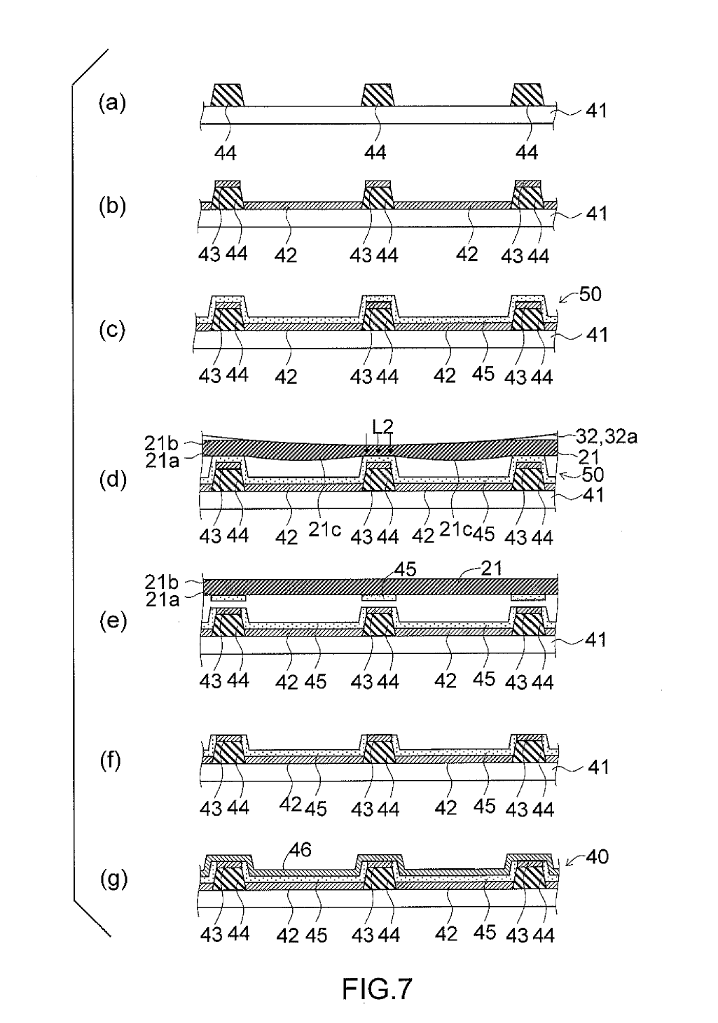

The examples where the first electrodes 42 and the auxiliary electrodes 43 are formed on the substrate 41 earlier than the protrusions 44 have been shown and described in the embodiments described above. These examples, however, are not restrictive and in a modification, the protrusions 44 may be formed on the substrate 41 earlier than the first electrodes 42 and the auxiliary electrodes 43. The close-fitting step and removal step in any one of the embodiments described above can be used in such a modification as well. This modification will be described below with reference to FIG. 7 (a) to (g).

First as shown in FIG. 7 (a), a plurality of protrusions 44 are formed on a substrate 41. Next as shown in FIG. 7 (b), a first electrode 42 is formed between every two of the protrusions 44. In addition, an auxiliary electrode 43 is formed on each of the protrusions 44. In this way, a plurality of first electrodes 42 electrically insulated from each other by the protrusions 44, and auxiliary electrodes 43 disposed on the protrusions 44 can be obtained. Instead, although this is not shown, first electrodes 42 may be formed on the substrate 41 first, next a protrusion 44 may be formed between every two of the first electrodes 42, and then an auxiliary electrode 43 may be formed on each of the protrusions.

After the formation of the electrodes 42 and 43, as shown in FIG. 7 (c), an organic semiconductor layer 45 is formed on the first electrodes 42, the auxiliary electrodes 43, and the protrusions 44. In this way, an intermediate product 50 can be obtained that includes the substrate 41, the first electrodes 42 disposed on the substrate 41, the auxiliary electrodes 43 and protrusions 44 disposed between the first electrodes 42, and the organic semiconductor layer 45 disposed on the first electrodes 42 and the auxiliary electrodes 43. In the present modification, the protrusions 44 are formed earlier than the auxiliary electrodes 43, and thus the protrusions 44 are covered with the auxiliary electrodes 3. The protrusions 44 do not need to have their upper surfaces covered with the auxiliary electrodes 43 over respective entire regions. In other words, the upper surfaces of the protrusions 44 need only to be at least partly covered with the auxiliary electrodes 43. In addition, an example of disposing the protrusions 44 in two rows between the first electrodes 42 and disposing the auxiliary electrode 43 between every two of the protrusions 44 has been shown and described in the above embodiments, but in the present modification, since one auxiliary electrode 43 is disposed on each of the protrusions 44, the protrusions 44 may only be disposed in one row between the first electrodes 42, as shown in FIG. 7 (c).

Next as shown in section FIG. 7 (d), the lid member close-fitting step is executed to press a part of the lid member 21 toward the stage 18 by use of the roller 31 of the lid member pressing mechanism 30 and thus bring the part of the first surface 21a of the lid member 21 into firm contact with a part of the intermediate product 50. In FIG. 7 (d) and FIG. 7 (e) that will be described later, the stage 18 on which the intermediate product 50 is mounted is omitted.

In the embodiment shown in FIG. 7 (d), part of the first surface 21a of the lid member 21 comes into firm contact with the section of the intermediate product 50 that is provided with the protrusions 44. At this time, as in the above embodiment, a shape curved along the outer circumferential surface 32a of the main body 32 is formed on the surface corresponding to the second surface 21b of the lid member 21 pressed by the main body 32 of the roller 31, that is, on the first surface 21a lying at the side opposite to the second surface 21b. Compared with the case where the first surface 21a of the lid member 21 is planar, therefore, this method allows the first surface 21a of the lid member 21 to be pressed firmly, without a clearance, against the section of the intermediate product 50 that is provided with the protrusions 44.

After the above pressing operation, the organic semiconductor layer 45 on the auxiliary electrode 43 positioned on a protrusion 44 is irradiated with the light L2, whereby as shown in FIG. 7 (e), the organic semiconductor layer 45 on the auxiliary electrode 43 becomes stuck to the lid member 21. FIG. 7 (f) shows a state in which the organic semiconductor layer 45 on the auxiliary electrode 43 positioned on the protrusion 44 has been removed. In the present modification, the lid member 21 comes into close contact with the organic semiconductor layer 45 to be removed. In this case, the organic semiconductor layer 45 on the auxiliary electrode 43 positioned on the protrusion 44 can be transferred to the first surface 21a of the lid member 21 without performing the irradiation with the light L2, by setting appropriate surface energy of the first surface 21a. That is to say, bringing the curved section 21c which is formed in curved shape of the lid member 21 into close contact with a part of the intermediate product 50 allows the organic semiconductor layer 45 on the auxiliary electrode 43 to be removed.

After the above removal, as shown in FIG. 7 (g), a second electrode 46 is formed on the organic semiconductor layers 45 positioned on the first electrodes 42, and on the auxiliary electrodes 43 positioned on the protrusions 44. In this manner, the organic semiconductor element 40 with the auxiliary electrodes 43 connected to the second electrode 46 can be obtained.

A Modification in which the Intermediate Product Processing Device is Configured as an Exposure Device

The examples where the intermediate product processing device 15 is configured as the removal device to remove part of the organic semiconductor layers 45 on the auxiliary electrodes 43 have been shown and described in the above embodiments and in a modification. Applications of the intermediate product processing device 15, however, are not limited to the examples. For example, although this is not shown, the intermediate product processing device 15 may be used as an exposure device that executes an exposure step in which it irradiates a desired layer of the intermediate product 50 with exposure light L2 while the lid member 21 is in close contact with the intermediate product 50.

A Modification in which the Intermediate Product Processing Device is Configured as a Vapor Deposition Device

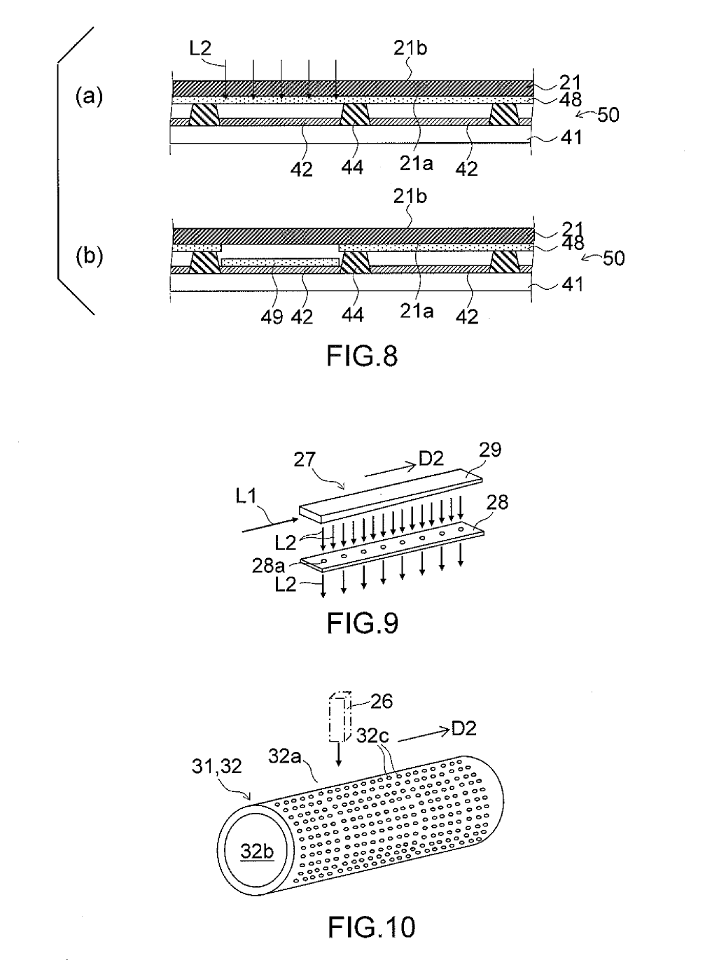

In an alternative modification, as shown in FIG. 8 (a) and FIG. 8 (b), the intermediate product processing device 15 may be used as a vapor deposition device that vapor-deposits a vapor-deposition material 48 on the substrate 41 by irradiating the material 48 with light while the lid member 21 is in close contact with the intermediate product 50.

In the present modification, as shown in FIG. 8 (a), the vapor deposition material 48 is disposed on the first surface 21a of the lid member 21. In addition, as shown in FIG. 8 (a), the intermediate product 50 includes the substrate 41, the plurality of protrusions 44 disposed on the substrate 41, and the first electrodes 42 each disposed between any two of the protrusions 44. In this case, the vapor deposition material 48 will evaporate when it is irradiated with light L2 such as infrared rays by use of the intermediate product processing device 15. More specifically as shown in FIG. 8 (a), when a region of the vapor deposition material 48 that is present at a position facing one of the first electrodes 42 is irradiated with the light L2, the vapor deposition material 48 will evaporate and stick to that first electrode 42 on the substrate 41. As a result, a vapor-deposited layer 49 can be formed on the corresponding first electrode 42, as shown in FIG. 8 (b). Additionally a space between the substrate 41 and the lid member 21 is appropriately partitioned by the protrusions 44. This prevents the vapor deposition material 48 from flying apart over a wide region in the space between the substrate 41 and the lid member 21.

The evaporation of the vapor deposition material 48 by heating is not limited to the method described above. For example, the vapor deposition material 48 may be heated by forming an infrared-light absorbing metallic thin film between the first surface 21a of the lid member 21 and the organic semiconductor layer 45 and emitting light toward the metallic thin film for heating. In this case, although substantially no light is directly applied to the vapor deposition material 48 provided on the first surface 21a of the lid member 21, the vapor deposition material 48 can be evaporated since it can be heated indirectly via the metallic thin film. Whether the vapor deposition material 48 is directly irradiated with the light or heated indirectly via the metallic thin film, it is common in that the light is emitted toward the section of the lid member 21 that is formed with the curved shape.

If the metallic thin film is formed from a magnetic material, for tighter contact between the lid member 21 and the intermediate product 50, magnetic fields may be generated around the lid member 21 or a magnetic body may be placed at an opposite side of the intermediate product 50 with respect to the lid member 21, thereby to generate a magnetic force that draws the lid member 21 toward the intermediate product 50.

### A Modification of the Optical System

The examples where the mirror 27a of the optical system is constructed to be movable along the rotational axis of the roller 31, in the internal space 32b of the main body 32 of the roller 31, have been shown and described in the above embodiments and modifications. These examples, however, are not intended to limit a more specific configuration of the optical system 27 for emitting light toward the plurality of sections/elements positioned on a plurality of lines represented along the second direction D2. For example as shown in FIG. 9, the optical system 27 may include a mask 28 and an optical waveguide 29, both arranged in the internal space 32b of the main body 32 of the roller 31. The mask 28 includes a plurality of openings 28a arranged in the second direction D2. The openings 28a in the mask 28 are arranged so that the light L2 that has passed through the openings 28a is guided to one or more of the organic semiconductor layer 45 to be removed from the intermediate product 50, a layer to be exposed to the light, the vapor deposition material 48, and the like. The waveguide 29 is configured so that the light L1 that has entered from an edge in the second direction D2 is guided to the mask 28 after being extracted at a substantially equal rate as the light L2 heading for the stage 18, at various positions in the second direction D2. As long as the light L1 from the light source 26 can be guided to the mask 28 at a substantially equal rate, the optical waveguide 29 may be replaced by other optical elements disposed upstream of the mask 28.

The light L2 that has been guided to the mask 28 first passes through the openings 28a of the mask 28, then passes through the main body 32 of the roller 31 and the lid member 21, and reaches the intermediate product 50. Accordingly the plurality of sections of the intermediate product 50 that are lined up in the second direction D2 can be simultaneously irradiated with the light L2. Therefore, the plurality of sections lined up in the second direction D2 can be irradiated with the light at the same time without moving the mirror 27a as in the above-described case. Hence the time required for the step can be reduced. In addition, irradiation with the light can be executed with higher positional accuracy since the mirror 27a is free from optical misalignment due to the movement of the mirror 27a.

### A Modification of the Roller

The examples where the main body 32 of the roller 31 is formed from a light-transmissive material that transmits light have also been shown and described in the above embodiments and modifications. The roller main body 32, however, does not have its configuration limited as long as the light L2 can pass through the curved section 21c of the lid member 21 and reach the intermediate product 50. For example as shown in FIG. 10, the main body 32 may be formed with a plurality of through-holes 32c lined up in the rotational direction R of the roller 31 and the rotational axis thereof, the through-holes 32c each extending from the outer circumferential surface 32a of the main body 32 to the internal space 32b. The through-holes 32c are arranged so that the light L2 that has passed through them is guided to one or more of the organic semiconductor layer 45 to be removed from the intermediate product 50, the layer to be exposed to the light, the vapor deposition material 48, and the like. In addition, the optical system 27 in the irradiation mechanism 25 is configured to allow the light L2 to first pass through the through-holes 32c in the main body 32, then pass through the lid member 21, and reach the intermediate product 50. The optical system 27 includes, for example, a mirror adapted to reflect light and thus change a traveling direction of the light, and a lens for focusing the light L2 upon the organic semiconductor layer 45. In this case, the lens is constructed so that the light that has been narrowed by it passes through the though-holes 32c.

If or when the through-holes 32c are formed on the main body 32 of the roller 31 as in the present modification, the material constituting the main body 32 can be not only a light-transmissive material that transmits light, but also such a metallic material as a material not allowing light to pass through. In accordance with the present modification, therefore, the material constituting the main body 32 can be selected easily. For example, the material of the main body 32 can be selected considering workability and availability, whereby the roller 31 can be improved in characteristics and a cost requirement of the roller 31 can be lowered.

In addition, in the present modification, even when as denoted by a dotted line in FIG. 10, the light source 26 is placed externally to the roller 31, light that has been emitted from the light source 26 can head for the intermediate product 50 through the through-holes 32c of the roller 31 after entering the internal space 32b of the roller 31 through the through-holes 32c thereof. Briefly in the present modification, the light source 26 and the optical system 27 can be arranged externally to the roller 31. This means that the light source 26 and the optical system 27 can be arranged with higher flexibility.

### Other Modifications of the Roller

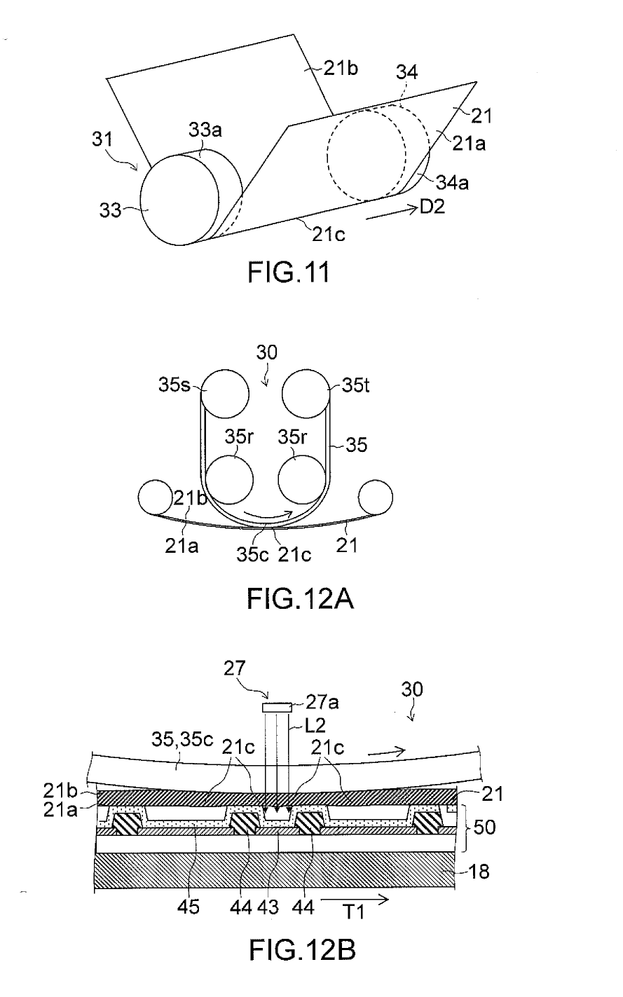

The examples where the lid member 21 is in contact over its entire lateral region with the roller 31 have been shown and described in the above embodiments and modifications. A more specific configuration of the roller 31, however, is not limited as long as the shape curved along the outer circumferential surface 32a of the roller main body 32 can be imparted to the first surface 21a of the lid member 21. For example as shown in FIG. 11, the roller 31 may include a first roller 33 and a second roller 34, both disposed spacedly in the second direction D2. The lid member 21 has its lateral direction matching to a direction of the rotational axis of the roller 31, that is, the second direction D2.

In the present modification, a section of the lid member 21 that lies between the first roller 33 and the second roller 34 is out of contact with outer circumferential surfaces of the rollers 33 and 34. Even in this case, if the lid member 21 has predetermined rigidity, a shape curved along the outer circumferential surfaces of the rollers 33 and 34 is formed on a region of the first surface 21a of the lid member 21 that corresponds to the second surface 21b directly pressed by the rollers 33, 34. More specifically in the present modification, as shown in FIG. 11, in addition to the first surface 21a at the opposite side relative to the second surface 21b directly pressed by the rollers 33, 34, a section having the curved shape, namely the curved section 21c is formed on a section of the first surface 21a of the lid member 21 that lies between the first roller 33 and the second roller 34. For this reason, the first surface 21a of the lid member 21 can be brought into close contact, without a clearance, with the section of the intermediate product 50 that includes the protrusions 44. Examples of a more specific configuration of the lid member 21 for assigning the predetermined rigidity to the lid member 21 include one obtained by forming the lid member 21 from a PET film and working the lid member 21 to within a 50-300 μm thickness range

In addition, in accordance with the present modification, the optical system 27 for guiding light to the intermediate product 50 via the curved section 21c of the lid member 21 can be disposed in the interspace between the first roller 33 and the second roller 34 or in a peripheral space therebetween. Accordingly the space for disposing the optical system does not need to be formed internally to the first roller 33 or the second roller 34. Furthermore, the flexibility of layout of the optical system 27 is enhanced relative to that obtained when the optical system 27 is disposed in an internal space of the rollers. Therefore, the light can be guided to the intermediate product 50 more easily and with higher accuracy.

### A Modification of the Lid Member Pressing Mechanism

The examples where the lid member pressing mechanism 30 for bringing part of the first surface 21a of the lid member 21 into close contact with part of the intermediate product 50 includes the roller 31 that presses part of the second surface 21b of the lid member 21 toward the intermediate product 50 have been shown and described in the above embodiments and modifications. A more specific configuration of the lid member pressing mechanism 3, however, is not limited as long as the shape protrudingly curved toward the intermediate product 50 is formed at least partially on the first surface 21a of the lid member 21 and the section of the lid member 21 that includes the curved shape is brought into close contact with a part of the intermediate product 50.

For example as shown in FIG. 12A, the lid material pressing mechanism 30 may include a pressurizing film of a long-size shape that is transported while being retained to form a shape protrudingly curved toward the lid member 21. FIG. 12A shows the way the pressurizing film 35 that has been unwound from an unwinder 35s is transported along one pair of guide rollers, 35r, and then rewound by a take-up section 35t. In this example, the pressurizing film 35 can be made to hold the curved section 35c between the paired guide rollers 35r, by appropriately setting the layout of the unwinder 35s, the take-up section 35t, and the paired guide rollers 35r, and elastic characteristics of the pressurizing film 35.

FIG. 12B is a diagram showing in enlarged form the way the lid member 21 is kept in close contact with the intermediate product 50 by being pressed from the pressurizing film 35 when the lid member pressing mechanism 30 has the pressurizing film 35. In the lid member pressing step according to the present modification, as shown in FIGS. 12A and 12B, when the curved section 35c of the pressurizing film 35 presses part of the second surface 21b of the lid member 21 toward the intermediate product 50, a shape curved along the curved section 35c of the pressurizing film 35 will be formed on a region of the first surface 21a that corresponds to the second surface 21b of the lid member 21. The first surface 21a of the lid member 21 can therefore be pressed firmly, without a clearance, against the section of the intermediate product 50 that includes the protrusions 44. Accordingly the organic semiconductor material that has flown apart from the surface of an auxiliary electrode 43 can be more reliably prevented from contaminating the organic semiconductor layer 45 on the first electrode 42, and an ambient environment.

In addition, in the present modification, as in the above-described embodiments, the pressurizing film 35 being transported can be used to configure the lid member pressing mechanism 30 and thus to bring the lid member 21 being transported at a synchronous speed, and the intermediate product 50 into close contact with one another to cover the intermediate product 50. Accordingly, various steps such as the irradiation step can be executed for the lid member 21 being transported and for the intermediate product 50. The organic semiconductor element 40 having high quality can therefore be efficiently manufactured at a low cost.

The material constituting the pressurizing film 35, and thickness, layer configuration, and other factors of the pressurizing film 35 are selected for an appropriate configuration of the curved section 35c. For example, a material having a coefficient of elasticity that is higher than that of the material constituting the lid member 21 is used as the material constituting the pressurizing film 35. In addition, the thickness of the pressurizing film 35 may be increased above that of the lid member 21 so that the curved section 35c is appropriately formed on the pressurizing film 35, between the paired guide rollers 35r. Alternatively a plurality of films may be stacked upon each other to form the pressurizing film 35. For example, the pressurizing film 35 may include one pair of films and an interference layer provided between the paired films. The paired films can be, for example, one pair of PET films each ranging from 100 to 500 μm in thickness. The interference layer may be formed using a light-transmissive material of a gel form. A light-transmissive optical pressure-sensitive adhesive, so-called an optical clear adhesive (OCA), can be used as the material for the interference layer.

In the present modification, the organic semiconductor material that has flown apart from an auxiliary electrode 43 of the intermediate product 50 sticks to the first surface 21a of the lid member 21. To manufacture the organic semiconductor element 40 having high quality, therefore, it is preferable that the lid member 21 with the organic semiconductor material sticking thereto be discarded without being reused during the manufacture of the organic semiconductor element 40. The organic semiconductor material, however, does not stick to the pressurizing film 35. In addition, as shown in FIG. 12A, the pressurizing film 35, after having pressed the lid member 21, is separated therefrom and rewound by the take-up section 35t. The pressurizing film 35 can therefore be reused during the manufacture of the organic semiconductor element 40 that follows the rewinding of the pressurizing film 35.

### A Modification of the Lid Member

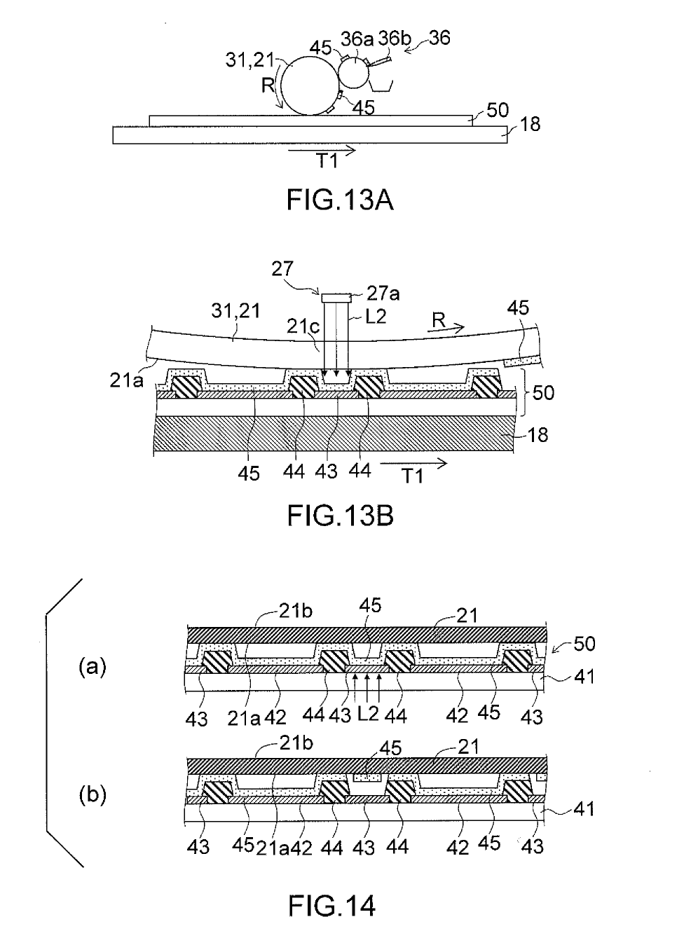

The examples where the lid member 21 including the first surface 21a and the second surface 21b is used as a member for covering the intermediate product 50 have been shown and described in the above embodiments and modifications. A more specific configuration of the lid member 21, however, is not limited as long as the intermediate product 50 can be appropriately covered using the curved shape. For example as shown in FIGS. 13A and 13B, the roller 31 may have its surface functioning as the first surface 21a of the lid member 21 that comes into close contact with a part of the intermediate product 50 and covers the intermediate product 50. In this example, the organic semiconductor layer 45 on the auxiliary electrode 43 can be removed by emitting the light L2 toward the organic semiconductor layer 45 on the auxiliary electrode 43 of the intermediate product 50 covered by the curved shape of the roller surface of the roller 31. In this case, the organic semiconductor material that has flown apart from the auxiliary electrode 43 sticks to the surface of the roller 31, thus forming an organic semiconductor layer 45 on the surface of the roller 31.

A cleaning mechanism 36 for cleaning the organic semiconductor layer 45 that has been formed on the surface of the roller 31 may be disposed as shown in FIG. 13A. For example, the cleaning mechanism 36 includes a pressure-sensitive roll 36a for peeling off the organic semiconductor layer 45 on the surface of the roller 31, and a blade 36b for removing the organic semiconductor layer 45 from a surface of the pressure-sensitive roll 36a. Disposing the cleaning mechanism 36 allows the intermediate product 50 to be continuously covered with the roller 31 having a clean surface.

While this is not shown, the roller 31 in the present modification may be one configured by winding a film. In this case, even if the surface of the roller 31 becomes contaminated with the organic semiconductor layer 45, the surface of the roller 31 can always be kept clean by unwinding the film having the organic semiconductor layer 45 sticking thereto, and removing this film. The cleaning mechanism 36 for cleaning the surface of the roller 31, therefore, becomes unnecessary.

### A Modification Relating to an Irradiating Direction of Light

The examples where the light L2 is emitted from a direction of the lid member 21, toward the organic semiconductor layer 45 provided on the auxiliary electrode 43, have been shown and described in the above embodiments and modifications. The direction in which the light L2 is emitted, however, is not limited as long as the organic semiconductor layer 45 can be appropriately heated. For example as shown in FIG. 14 (a), the light L2 may be emitted from the direction of the lid member 21 within the intermediate product 50, toward the lid member 21 in close contact with the intermediate product 50. The auxiliary electrode 43 here is commonly constituted by one metallic element or an alloy of metallic elements. The light L2 that has been emitted toward the lid member 21 in close contact with the intermediate product 50 is therefore shielded primarily by the auxiliary electrode 43. In this case, light of a wavelength allowing the auxiliary electrode 43 to absorb the light can be used to heat the auxiliary electrode 43 and thus heat the organic semiconductor layer 45 on the auxiliary electrode 43. Consequently, as shown in FIG. 14 (b), the organic semiconductor layer 45 on the auxiliary electrode 43 can be evaporated and stuck to the first surface 21a of the lid member 21. If the light L2 is predetermined, the material constituting the auxiliary electrode 43 can be one capable of absorbing the light L2.

### Other Modifications

The examples where, when the plurality of intermediate products 50 lined up in the first direction D1 are irradiated with the light L2 in order, the stage 18 moves in the moving direction T1 of the stage and the optical system 27 of the irradiation mechanism 25 remains at rest, have been shown and described in the above embodiments and modifications. The present invention, however, is not limited to these examples and when the plurality of intermediate products 50 lined up in the first direction D1 are irradiated with the light L2 in order, the stage 18 may remain at rest and the optical system 27 may move in the first direction D1.

The example where the stage 18 is used as a mechanism for transporting the intermediate product 50 has been shown and described in the above embodiments and modifications. However, this example is not intended to limit applications of the present invention and although this is not shown, the intermediate product 50 may be supplied and transported in roll-to-roll form. That is to say, the substrate 41 of the intermediate product 50 may extend in long-size form and the first electrodes 42, auxiliary electrodes 43, protrusions 44, organic semiconductor layers 45, second electrode 46, and the like of the intermediate product 50 may be formed on the substrate 41 that extends in the long-size form. In this case, the mechanism for transporting the intermediate product 50 in the direction T1 can be a general transport mechanism used in the roll-to-roll form.

The example where the organic semiconductor element 40 is an organic EL element has been shown and described in the above embodiments and modifications. However, this does not limit a type of the organic semiconductor element manufactured using the above-described element manufacturing apparatus 10 and element manufacturing method. For example, various organic semiconductor elements such as organic transistor devices and organic solar-cell devices can be manufactured using the element manufacturing apparatus 10 and the element manufacturing method. The organic semiconductor layers and other constituent elements used in organic transistor devices can be known ones, for example, those described in JP2009-87996A. In addition, the organic semiconductor layers and other elements used in an organic solar cell device can be known ones, for example, those described in JP2011-151195A. In addition, the element manufacturing apparatus 10 and the element manufacturing method may be applied to manufacturing inorganic semiconductor elements as well as to organic semiconductor elements.

The example where the constituent elements of the intermediate product processing device 15 are arranged inside the chamber maintained in a vacuum atmosphere has been shown and described in the above embodiments and modifications. That is to say, the example where the step of irradiating the intermediate product 50 with light by use of the intermediate product processing device 15 is executed under a vacuum environment has been shown and described. The example, however, is not intended to limit applications of the present invention, and the step of irradiating the intermediate product 50 with light by use of the intermediate product processing device 15 may be executed under a non-vacuum environment such as an atmospheric pressure environment.

While several modifications of the embodiments have been described, naturally these modifications may also be applied in combination as appropriate.

### DESCRIPTION OF REFERENCE CHARACTERS

10: Element manufacturing apparatus
15: Intermediate product processing device
18: Stage
20: Lid member supply mechanism
21: Lid member
25: Irradiation mechanism
26: Light source
27: Optical system
30: Lid member pressing mechanism
31: Roller
35: Pressurizing film
36: Cleaning mechanism
40: Organic semiconductor element
41: Substrate
42: First electrode
43: Auxiliary electrode
44: Protrusion
45: Organic semiconductor layer
46: Second electrode
50: Intermediate product

1-24. (canceled)

25. An element manufacturing method for forming an element on a substrate, the method comprising the steps of:
providing an intermediate product that includes the substrate and a plurality of protrusions each disposed on the substrate;
providing a lid member having a first surface, the lid member being provided so that the first surface faces toward the protrusions of the intermediate product; and
pressing the lid member to bring a part of the first surface thereof into close contact with a part of the intermediate product, wherein:
in the lid member pressing step, on the first surface of the lid member, a shape protrudingly curved toward the intermediate product is formed and a section of the lid member that includes the curved shape is brought into close contact with a part of the intermediate product, and
the element manufacturing method comprises an irradiation step to emit light toward a section of the lid member that is formed with the curved shape.

26. The element manufacturing method according to claim 25, wherein:
in addition to the first surface, the lid member includes a second surface that lies on a side opposite to the first surface; and
in the lid member pressing step, part of the second surface of the lid member is pressed toward the intermediate product by use of a lid member pressing mechanism to bring a part of the first surface of the lid member into close contact with a part of the intermediate product,
the lid member pressing mechanism includes a roller that rotates around a rotational axis of the roller,
in the lid member pressing step, when the roller presses part of the second surface of the lid member toward the intermediate product, a shape curved along an outer circumferential surface of the roller will be formed on a region of the first surface of the lid member that corresponds to the second surface thereof, and
in the irradiation step, the light is guided by an optical system fixed with respect to the rotation of the roller, passes through the lid member, and reaches the intermediate product.

27. The element manufacturing method according to claim 25, wherein:
in the irradiation step, the light passes through the section of the lid member that is formed with the curved shape, and reaches the intermediate product.

28. The element manufacturing method according to claim 25, wherein:
in the irradiation step, the light is emitted from a direction of the lid member within the intermediate product, toward the lid member in close contact with the intermediate product.

29. The element manufacturing method according to claim 26, wherein:
the roller includes a main body constructed of a light-transmissive material to transmit light, the main body constituting the outer circumferential surface of the roller; and
in the irradiation step, after the light has passed through an internal space of the roller, the light passes through the main body of the roller and the lid member and reaches the intermediate product.

30. The element manufacturing method according to claim 29, wherein:
a mask with a plurality of openings is disposed in the internal space of the roller; and
in the irradiation step, after the light has passed through the openings of the mask, the light passes through the main body of the roller and the lid member and reaches the intermediate product.

31. The element manufacturing method according to claim 26, wherein:
the roller includes a main body internally formed with a space, the main body constituting the outer circumferential surface of the roller;
a plurality of through-holes each extending from the outer circumferential surface to the internal space are formed on the main body; and
in the irradiation step, after the light has passed through the through-holes of the main body, the light passes through the lid member and reaches the intermediate product.

32. An element manufacturing method for forming an element on a substrate, the method comprising the steps of:
providing an intermediate product that includes the substrate and a plurality of protrusions each disposed on the substrate;
providing a lid member having a first surface, the lid member being provided so that the first surface faces toward the protrusions of the intermediate product; and
pressing the lid member to bring a part of the first surface thereof into close contact with a part of the intermediate product, wherein:
in the lid member pressing step, on the first surface of the lid member, a shape protrudingly curved toward the intermediate product is formed and a section of the lid member that includes the curved shape is brought into close contact with a part of the intermediate product,
the element includes the substrate, a plurality of first electrodes each disposed on the substrate, auxiliary electrodes each disposed between any two of the first electrodes, the protrusions also each disposed between any two of the first electrodes, an organic semiconductor layer disposed on the first electrodes, and a second electrode disposed on the organic semiconductor layer and the auxiliary electrodes;
the intermediate product includes the substrate, the first electrodes disposed on the substrate, the auxiliary electrodes and protrusions each disposed between any two of the first electrodes, and the organic semiconductor layer disposed on the first electrodes and the auxiliary electrodes; and
the organic semiconductor layer disposed on one of the auxiliary electrodes is removed while the section of the lid member that is formed with the curved shape is in close contact with a part of the intermediate product.

33. An element manufacturing apparatus for forming an element on a substrate, the apparatus comprising:
a transport mechanism for transporting an intermediate product including the substrate and a plurality of protrusions each disposed on the substrate;
a lid member supply mechanism for supplying a lid member having a first surface, the mechanism supplying the lid member so that the first surface faces the protrusions of the intermediate product; and
a lid member pressing mechanism for bringing a part of the first surface of the lid member into close contact with a part of the intermediate product, wherein:
on the first surface of the lid member that is being pressed by the lid member pressing mechanism, a shape protrudingly curved toward the intermediate product is formed and a section of the lid member that includes the curved shape is brought into close contact with a part of the intermediate product, and
the element manufacturing apparatus comprises an irradiation mechanism for emitting light toward a section of the lid member that is formed with the curved shape.

34. The element manufacturing apparatus according to claim 33, wherein:
in addition to the first surface, the lid member includes a second surface that lies on a side opposite to the first surface,
when the lid member pressing mechanism presses a part of the second surface of the lid member toward the intermediate product, part of the first surface of the lid member will come into close contact with a part of the intermediate product,
the lid member pressing mechanism includes a roller that rotates around a rotational axis of the roller,
a shape curved along an outer circumferential surface of the roller is formed on a region of the first surface of the lid member that corresponds to the second surface thereof that is being pressed by the roller,
the irradiation mechanism includes an optical system that guides the light so that the light will pass through the lid member and reach the intermediate product; and
the optical system is fixed with respect to the rotation of the roller.

35. The element manufacturing apparatus according to claim 33, wherein:
the light passes through the section of the lid member that is formed with the curved shape, and reaches the intermediate product.

36. The element manufacturing apparatus according to claim 33, wherein:
the light is emitted from a direction of the lid member within the intermediate product, toward the lid member in close contact with the intermediate product.

37. The element manufacturing apparatus according to claim 34, wherein:
the roller includes a main body constructed of a light-transmissive material to transmit light and internally formed with a space, the main body constituting the outer circumferential surface of the roller; and
the irradiation mechanism is configured so that the light, after passing through an internal space of the roller, passes through the main body and the lid member and reaches the intermediate product.

38. The element manufacturing apparatus according to claim 37, wherein:
a mask with a plurality of openings is disposed in the internal space of the roller; and
the irradiation mechanism is configured so that the light, after passing through the openings of the mask, passes through the main body and the lid member and reaches the intermediate product.

39. The element manufacturing apparatus according to claim 34, wherein:
the roller includes a main body internally formed with a space, the main body constituting the outer circumferential surface of the roller;
a plurality of through-holes each extending from the outer circumferential surface to the internal space are formed on the main body; and
the irradiation mechanism is configured so that the light, after passing through the through-holes of the main body, passes through the lid member and reaches the intermediate product.

40. The element manufacturing apparatus according to claim 34, wherein:
the roller includes a first roller and a second roller, both lined up spacedly; and
when the first roller and the second roller act together to press the second surface of the lid member, a section of the lid member that is positioned between the first roller and the second roller will have a shape curved along an outer circumferential surface of the first roller and an outer circumferential surface of the second roller.
